(19) United States
(12) Patent Application Publication
(10) Pub. No.: US 2011/0031576 A1
(43) Pub. Date: Feb. 10, 2011

(54) SOLID-STATE IMAGING DEVICE AND MANUFACTURING METHOD THEREOF

(75) Inventors: Seiichi Iwasa, Oita (JP); Yoshio Kasai, Oita (JP); Takeshi Yousyou, Oita (JP); Tsutomu Sato, Oita (JP); Atsushi Murakoshi, Oita (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/722,716

(22) Filed: Mar. 12, 2010

(30) Foreign Application Priority Data
Aug. 10, 2009 (JP) 2009-186040

(51) Int. Cl. H01L 27/146; H01L 21/265

(52) U.S. Cl. 257/440; 438/73; 257/E27.133; 257/E21.334

(57) ABSTRACT

A solid-state imaging device includes a first-conductive semiconductor layer, a second-conductive semiconductor layer that is provided on the first-conductive semiconductor layer, a light receiving element that is formed in the second-conductive semiconductor layer, and an element isolation region that is formed to surround the light receiving element in an in-plane direction of the second-conductive semiconductor layer, in which the element isolation region includes a first-conductive first element isolation unit that is connected to the first-conductive semiconductor layer, a hollow that is formed on the first-conductive first element isolation unit, and a first-conductive second element isolation unit that is formed on the hollow.

### CROSS-REFERENCE TO RELATED APPLICATIONS

This application is based upon and claims the benefit of priority from the prior Japanese Patent Application No. 2009-186040, filed on Aug. 10, 2009; the entire contents of which are incorporated herein by reference.

### BACKGROUND OF THE INVENTION

1. Field of the Invention

The present invention relates to a solid-state imaging device and a manufacturing method thereof.

2. Description of the Related Art

In recent years, use of a complementary metal oxide semiconductor (CMOS) image sensor has expanded remarkably. Specially, the number of pixels of the CMOS image sensor mounted on a cellular phone has been integrated rapidly, and therefore there is a market need for miniaturization of the CMOS image sensor and progress in improvement of optical characteristics. Under such a background, introduction of a waveguide and a structure of receiving light from a back side of a semiconductor substrate are proposed as a method for increasing the number of saturated electrons in a photodiode formed on the semiconductor substrate. Both of them need an element isolation and diffusion layer for the photodiode as a light receiving element with a sufficient width, and a light receiving unit having a volume as desired and a surface layer having an area as desired.

In performing element isolation between adjacent light receiving elements in the CMOS image sensor, for example, in Japanese Patent Application Laid-open No. 2008-84962, an ion implantation is performed in multiple stages until impurities reach the depth of, for example, about 4 μm for the element isolation in the semiconductor substrate.

However, in the case of performing such an ion implantation in multiple stages, if an aspect ratio of an opening of a mask material provided in an ion implantation region in the ion implantation becomes high with the progress of miniaturization, an acceleration energy loss increases at the time of the ion implantation. Specially, this tendency is remarkable in an ion implantation condition with low acceleration energy, and an impurity concentration of an element isolation layer on the surface layer side of the semiconductor substrate becomes high. In this case, the element isolation layer expands to a light receiving element region due to the thermal diffusion and therefore the volume of the light receiving element region decreases, which results in decrease in the number of saturated electrons and influence (color mixing) on adjacent light receiving element.

### BRIEF SUMMARY OF THE INVENTION

A solid-state imaging device according to an embodiment of the present invention comprises: a first-conductive semiconductor layer; a second-conductive semiconductor layer that is provided on the first-conductive semiconductor layer; a light receiving element that is formed in the second-conductive semiconductor layer; and an element isolation region that is formed to surround the light receiving element in an in-plane direction of the second-conductive semiconductor layer, wherein the element isolation region includes a first-conductive first element isolation unit that is connected to the first-conductive semiconductor layer, a hollow that is formed on the first-conductive first element isolation unit, and a first-conductive second element isolation unit that is formed on the hollow.

A method of manufacturing a solid-state imaging device according to an embodiment of the present invention comprises: forming a second-conductive semiconductor layer on a first-conductive semiconductor layer; forming an opening to surround a predetermined region of the second-conductive semiconductor layer in an in-plane direction of the second-conductive semiconductor layer; forming a hollow by sealing the opening through a thermal treatment to the second-conductive semiconductor layer in a non-oxidative atmosphere; forming a pattern in which a region corresponding to the hollow is open on the second-conductive semiconductor layer; forming an element isolation unit by performing an ion implantation of a first-conductive ion on the second-conductive semiconductor layer with the pattern as a mask; and forming a light receiving element on the second-conductive semiconductor layer surrounded by the element isolation unit and the hollow in the in-plane direction of the second-conductive semiconductor layer.

### BRIEF DESCRIPTION OF THE DRAWINGS

FIGS. 1A and 1B are diagrams schematically illustrating a configuration of a semiconductor device according to an embodiment of the present invention;

FIGS. 2A to 2F are cross-sectional views explaining an example of a manufacturing process of the semiconductor device according to the embodiment of the present invention; and

FIG. 3 is a schematic diagram for explaining a scattering probability when an ion implantation is performed on a semiconductor substrate from an opening of a mask layer.

### DETAILED DESCRIPTION OF THE INVENTION

Embodiments of a solid-state imaging device and a manufacturing method thereof according to the present invention are explained in detail below with reference to the accompanying drawings. The present invention is not limited to the following description and can be appropriately modified within the range not departing from the gist of the present invention. Moreover, in the following drawings, the scale of each component may be different from the realistic one for easy understanding, and the same can be said between the drawings.

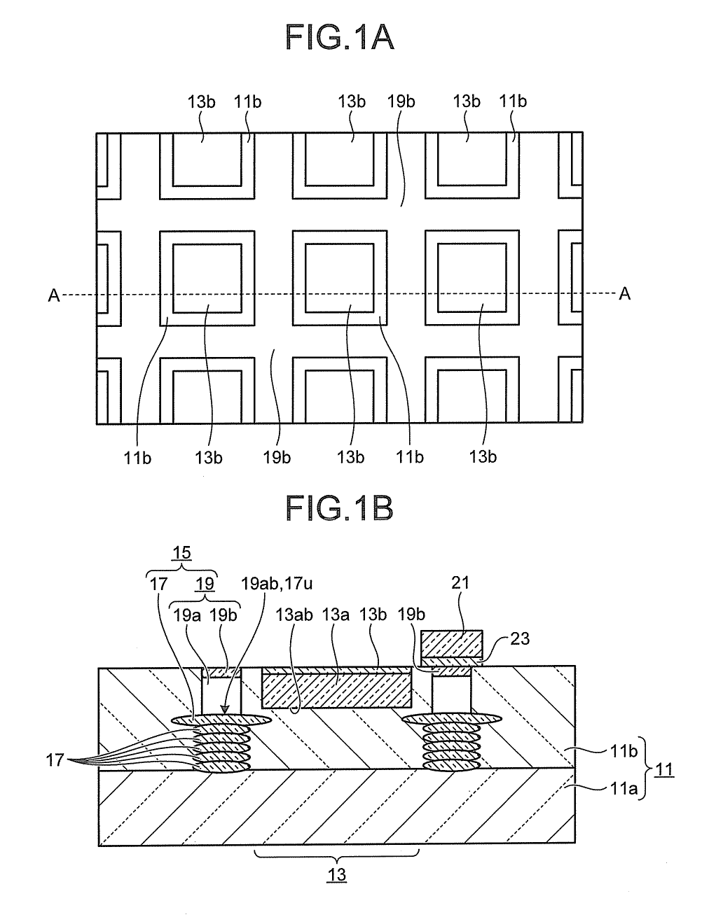

FIGS. 1A and 1B are diagrams schematically illustrating a configuration of a solid-state imaging device according to an embodiment of the present invention, in which FIG. 1A is a plan view and FIG. 1B is a cross-sectional view of an essential portion taken along line A-A in FIG. 1A. A semiconductor device according to the present embodiment is a CMOS-type solid-state imaging device (CMOS image sensor).

As shown in FIGS. 1A and 1B, a semiconductor substrate 11 is composed of an N/P substrate having a two-layer semiconductor structure, in which an N-type semiconductor layer (N-type epitaxial layer) 11b that is a second-type semiconductor layer as a semiconductor layer with extremely few defects is laminated on a P-type semiconductor substrate 11a that is a first-type base substrate by an epitaxial growth. The thickness of the P-type semiconductor substrate 11a is, for example, 800 μm, and the thickness of the N-type epitaxial layer 11b is, for example, 4 μm. The material of the semiconductor substrate 11 can be selected from, for example, Si, Ge, SiGe, SiC, SiSn, PbS, GaAs, InP, GaP, GaN, GaAlAs, GaInAsP, and ZnSe. In the present embodiment, explanation is given for a case in which the semiconductor substrate 11 is made of silicon (Si).

An N-type charge storage layer 13a that is a photoelectric conversion unit of a photodiode 13 is formed by the ion implantation of, for example, phosphorus (P) on an area of a part of the N-type epitaxial layer 11b. The peak depth of P concentration of the charge storage layer 13a is determined mainly by the energy at the time of the P ion implantation. A shield layer 13b containing P-type impurities, for example, boron (B), with relatively high concentration is formed on the charge storage layer 13a at a portion near the surface of the photodiode 13.

In the case where the N/P substrate as described above is used, if the charge storage layer 13a of the photodiode is only formed on the N-type epitaxial layer 11b, adjacent photodiodes are electrically connected with each other. When the photodiodes are electrically connected, electrons generated in the photodiode are not converted into a proper signal for a pixel on which signal processing needs to be performed.

Therefore, in the present embodiment, in order to electrically isolate from the charge storage layer 13a of each of the other adjacent photodiodes 13, a plurality of first element isolation units 17 that is composed of P-type semiconductor regions (impurity diffusion layers) in which P-type impurities (e.g., B ions) are ion-implanted in multiple stages by an accelerator and which extend in a direction approximately vertical to an in-plane direction of the semiconductor substrate 11, and a second element isolation unit 19 having an Si-on-nothing (SON) structure that is provided on the first element isolation units 17 are provided as an element isolation region 15 of the photodiode 13 in a region surrounding the charge storage layer 13a of the photodiode in the in-plane direction of the semiconductor substrate 11.

Moreover, the semiconductor device according to the present embodiment includes a readout gate electrode 21 of a transfer transistor (not shown) that controls readout of charges stored in the charge storage layer 13a on the second element isolation unit 19 via a gate insulating film 23.

The semiconductor device according to the present embodiment includes a plurality of the first element isolation units 17 composed of the P-type semiconductor layers and the second element isolation unit 19 having the SON structure that is provided on the first element isolation units 17 as the element isolation region 15 of the photodiode 13 as described above. The second element isolation unit 19 includes a hollow 19a positioned on the uppermost layer of the first element isolation units 17 and a sealing layer 19b composed of a first conductive silicon layer that seals the upper portion of the hollow 19a at a surface approximately coplanar with the surface of the N-type epitaxial layer 11b. The lowermost layer of the first element isolation units 17 is connected to the P-type semiconductor substrate 11a.

With this structure, the element isolation region 15 and the P-type semiconductor substrate 11a function as a barrier layer that three-dimensionally (sterically) surrounds the charge storage layer 13a of the photodiode 13 to electrically isolate from the charge storage layer 13a of each of the other adjacent photodiodes 13.

The depth that light reaches from the light receiving surface in the semiconductor substrate 11 made of silicon is 320 nm in blue light, 790 nm in green light, and 3 μm in red light. The depth position of a lower end portion 13ab of the charge storage layer, which is the bottom portion of the N-type charge storage layer 13a, is set to the depth position equal to or more than the depth that light of each color reaches for each light receiving element based on the depth that light of each color reaches for effectively performing the photoelectric conversion by light of each color. The depth position of a bottom portion 19ab of the hollow, i.e., the depth position of an upper end portion 17u of the first element isolation units is set to the depth position equal to or more than the depth (the set depth of the lower end portion 13ab of the charge storage layer) that is set as the lower end portion 13ab of the charge storage layer for effectively performing the photoelectric conversion by light of each color in the N-type charge storage layer 13a. In practice, the exact boundary of the lower end portion 13ab of the charge storage layer that is the bottom portion of the N-type charge storage layer 13a is hard to recognize due to the impurity diffusion between the N-type charge storage layer 13a and the N-type epitaxial layer 11b.

In the present embodiment, the thickness of the N-type epitaxial layer 11b is set to, for example, 4 μm with the depth that red light reaches from the light receiving surface in the semiconductor substrate 11 as a reference. The depth position of the lower end portion 13ab of the charge storage layer is set to, for example, about 320 nm with the depth (320 nm) that blue light reaches from the light receiving surface in the semiconductor substrate 11 as a reference, and is set to, for example, about 790 nm with the depth (790 nm) that green light reaches from the light receiving surface in the semiconductor substrate 11 as a reference.

In the present embodiment, the depth position of the bottom portion 19ab of the hollow, i.e., the depth position of the upper end portion 17u of the first element isolation units, is set to the position deeper than the set depth position of the lower end portion 13ab of the charge storage layer and is about 320 nm to 790 nm with the depth that blue light and green light reach from the light receiving surface in the semiconductor substrate 11 as a reference.

The first element isolation unit 17 positioned in the uppermost layer among a plurality of the first element isolation units 17 has the P-type impurity concentration higher than other first element isolation units 17 positioned in the lower layer in the in-plane direction of the semiconductor substrate 11 and expands in a direction of the charge storage layer 13a. This is because when forming the first element isolation units 17 by the ion implantation, the impurity concentration of the first element isolation unit 17 on the surface layer side of the N-type epitaxial layer 11b becomes high due to the acceleration energy loss or the like at the time of the ion implantation and therefore the first element isolation unit 17 expands by the thermal diffusion as described later.

However, as described above, the depth position of the bottom portion 19ab of the hollow, i.e., the depth position of the upper end portion 17u of the first element isolation units, is set to the depth position equal to or more than the set depth of the lower end portion 13ab of the charge storage layer. Whereby, even if the first element isolation unit 17 positioned in the uppermost layer expands in the direction of the charge storage layer 13a, the light receiving element region effective for the photoelectric conversion in the N-type charge storage layer 13a is not penetrated. In other words, the volume of the effective light receiving element region of the charge storage layer 13a is prevented from decreasing due to the first element isolation unit 17. Therefore, decrease in the number of saturated electrons in the N-type charge storage layer 13a and the influence (color mixing) on the adjacent light receiving element due to the expansion of the first element isolation unit 17 are prevented.

In the semiconductor device according to the present embodiment configured as above, the element isolation region 15 that includes a plurality of the first element isolation units 17 composed of the P-type semiconductor layers and the second element isolation unit 19 having the SON structure is included in the region surrounding the charge storage layer 13a of the photodiode 13 in the in-plane direction of the semiconductor substrate 11, and the element isolation region 15 is connected to the P-type semiconductor substrate 11a. Whereby, the charge storage layers 13a of the photodiodes 13 can be electrically isolated from each other by individually and three-dimensionally (sterically) surrounding them by the element isolation regions 15 and the P-type semiconductor substrate 11a.

The depth position of the bottom portion 19ab of the hollow, i.e., the depth position of the upper end portion 17u of the first element isolation units, is set to the position that is deep equal to or more than the set depth of the lower end portion 13ab of the charge storage layer, so that it is prevented that the first element isolation unit 17 penetrates the region of the charge storage layer 13a and thus the volume of the light receiving element region decreases. Therefore, decrease in the number of saturated electrons and the influence (color mixing) on the adjacent light receiving element due to the expansion of the first element isolation unit 17 are prevented.

Thus, according to the semiconductor device in the present embodiment, it is possible to realize a high-quality semiconductor device, in which adjacent photodiodes are electrically isolated from each other certainly and which prevent decrease in the number of saturated electrons and the color mixing of the light receiving element due to the expansion of the element isolation layer even with the progress of miniaturization.

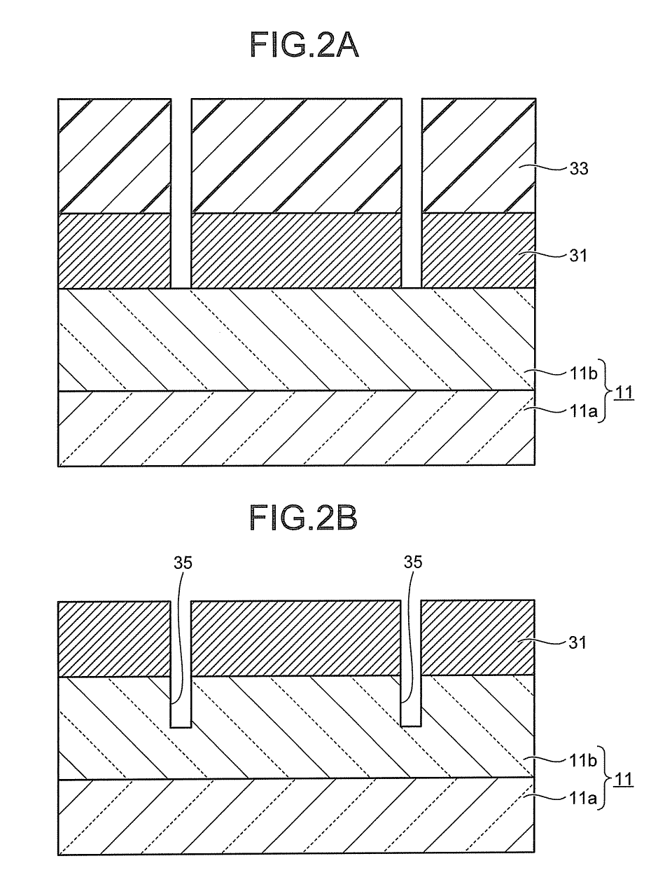

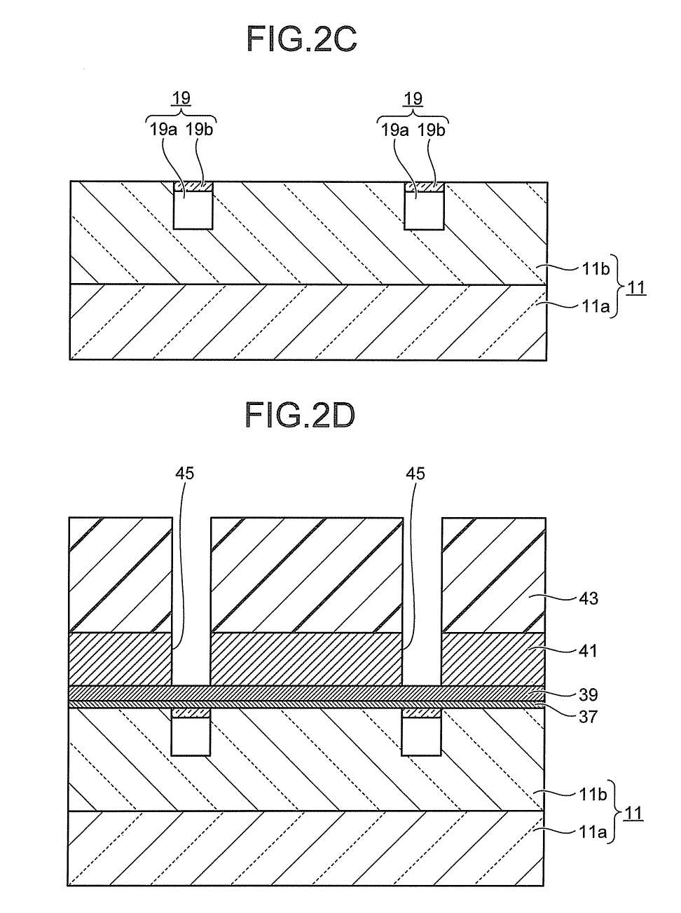

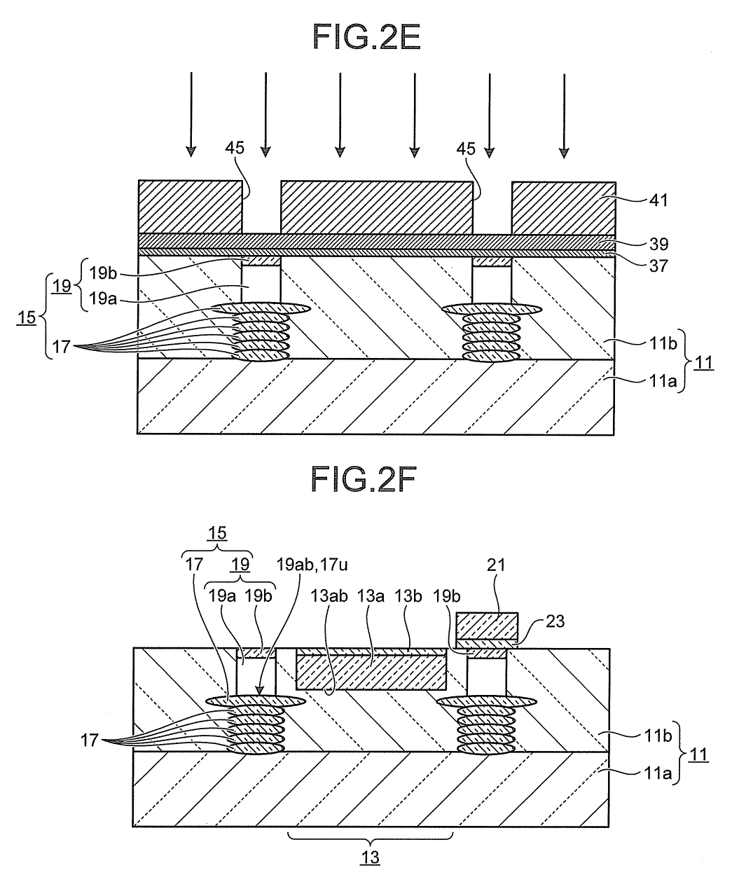

Next, explanation is given for an example of a manufacturing process of the semiconductor device according to the present embodiment with reference to FIG. 2A to FIG. 2F. FIGS. 2A to 2F are cross-sectional views explaining an example of the manufacturing process of the semiconductor device according to the present embodiment. First, the semiconductor substrate 11 that is the N/P substrate having a two-layer structure is prepared. When manufacturing the N/P substrate, a P-type silicon (Si) substrate is used as the P-type semiconductor substrate 11a that is a base substrate, on which the N-type epitaxial layer 11b is deposited by the epitaxial growth. The thickness of the P-type semiconductor substrate 11a is, for example, 800 μm, and the thickness of the N-type epitaxial layer 11b is, for example, 4 μm.

Next, a silicon dioxide film (SiO₂ film) with a film thickness of about 5 μm is deposited as a mask layer 31 on the semiconductor substrate 11, for example, by a chemical vapor deposition (CVD) method. Then, a photoresist pattern 33 is formed on the mask layer 31 by using the lithographic technique. The photoresist pattern 33 has openings in a lattice shape at the positions at which the element isolation regions 15 are to be formed in the in-plane direction of the semiconductor substrate 11.

Next, the anisotropic etching, for example, the reactive ion etching (RIE), is performed on the mask layer 31 until reaching the N-type epitaxial layer 11b with the photoresist pattern 33 as an etching mask to transfer the pattern of the photoresist pattern 33 onto the mask layer 31 as shown in FIG. 2A.

Next, after carbonizing and isolating the photoresist pattern 33, the patterning is performed on the semiconductor substrate 11 by the anisotropic etching, for example, the RIE with the mask layer 31 onto which the pattern is transferred as the etching mask to form a two-dimensional array of trenches 35 with a depth of about 2 μm in the surface layer of the N-type epitaxial layer 11b of the semiconductor substrate 11 as shown in FIG. 2B. The trenches 35 are formed in a lattice shape corresponding to the positions at which the element isolation regions 15 are to be formed. The width of the trench 35 and the distance between the adjacent trenches 35 are appropriately set in accordance with the pixel pitch of the CMOS image sensor.

The mask layer 31 is preferably made of a material (material of which selectivity with respect to silicon is large) of which etching rate is sufficiently slow compared with silicon when the patterning is performed on the semiconductor substrate 11 by the anisotropic etching. For example, when the RIE is used for the anisotropic etching, a silicon dioxide film, a laminated film of a silicon nitride film and a silicon dioxide film, or the like are suitable.

Next, after completely removing the mask layer 31 by a buffered hydrofluoric acid solution, high temperature annealing is performed for about 10 minutes in the non-oxidative atmosphere under high temperature and reduced pressure (pressure lower than the atmospheric pressure), preferably, the atmosphere in which SiO₂ is reduced, e.g., a 100% hydrogen atmosphere at 1050° C. and 10 torr, so that the opening surface of each trench 35 is closed by the sealing layer 19b composed of a silicon layer under which the hollow is formed as shown in FIG. 2C. Whereby, the hollows 19a are formed in the semiconductor substrate 11, and the two-dimensional array of the second element isolation units 19 is formed. The second element isolation units 19 are formed in a lattice shape corresponding to the positions at which the element isolation regions 15 are to be formed.

This form change is due to the surface migration of silicon that is caused to minimize the surface energy after the silicon dioxide film on the surface of the semiconductor substrate 11 is removed. Whereby, the second element isolation unit 19 having the SON structure that includes the hollow 19a and the sealing layer 19b can be formed in the region in which the trench 35 is formed. In this example, the thermal treatment temperature is set to 1050° C., however, can be higher than 1050° C. If the depth of the trench 35 is too large, the hollow 19a is divided up and down due to the migration, so that care is required for the depth of the trench 35.

The method of forming the SON structure is described in detail in “Tsutomu Sato et al., “Fabrication of Silicon-on-Nothing Structure by Substrate Engineering Using the Empty-Space-in-Silicon Formation Technique” 2004 Japanese Journal of Applied Physics Vol. 43, No. 1, pp 12 to 18.” and Japanese Patent Application Laid-open No. 2001-144276.

Next, an oxide film 37 with a film thickness of about 10 nm, a silicon nitride film 39 with a film thickness of about 100 nm, and a hard mask layer (oxide film) 41 with a film thickness of about 5 μm, are deposited on the semiconductor substrate 11. Then, for forming the element isolation, layer of the photodiode, a photoresist pattern 43 in which punched pattern portions are overlapped with the regions of the SON structure is formed on the hard mask layer (oxide film) 41 by using the lithographic technique.

Next, the anisotropic etching, for example, the reactive ion etching (RIE), is performed on the hard mask layer (oxide film) 41 until reaching the silicon nitride film 39 with the photoresist pattern 43 as an etching mask to transfer the punched pattern of the photoresist pattern 43 onto the hard mask layer (oxide film) 41 as shown in FIG. 2D, thereby forming a two-dimensional array of grooves 45. The grooves 45 are formed in a lattice shape corresponding to the positions of the second element isolation units 19.

Next, after carbonizing and isolating the photoresist pattern 43, the ion implantation of P-type impurities is performed in multiple stages on the semiconductor substrate 11 from the grooves 45 as shown in FIG. 2E by using the hard mask layer (oxide film) 41 in which the grooves 45 are formed as an ion-implantation mask. At this time, the N-type epitaxial layer 11b with a thickness of about 4 μm is laminated on the P-type semiconductor substrate 11a in the semiconductor substrate 11, and the ion implantation of, for example, boron (B) as P-type impurities is performed on the surface layer of the N-type epitaxial layer 11b until reaching the P-type semiconductor substrate 11a while dividing the depth equally and changing the implantation condition in multiple stages.

In the present embodiment, the ion implantation of B is performed six times while changing the implantation condition for forming the first element isolation units 17 as the P-type semiconductor regions in six layers on the lower side of the second element isolation unit 19. In this manner, when B ions are implanted, the N-type epitaxial layer 11b between the bottom portion of the hollow 19a of the second element isolation unit 19 and the surface layer portion of the P-type semiconductor substrate 11a is filled with the six layers of the first element isolation units 17 with no space to be substantially the P-type semiconductor. Consequently, as shown in FIG. 2E, the element isolation regions 15 are formed. The first element isolation unit 17 positioned in the uppermost layer has the P-type impurity concentration higher than other first element isolation units 17 positioned in the lower layer in the in-plane direction of the semiconductor substrate 11 and expands in the direction of the charge storage layer 13a.

Next, after completely removing the oxide film 37, the silicon nitride film 39, and the hard mask layer (oxide film) 41, the N-type charge storage layers 13a as photoelectric conversion units of the photodiodes 13 are formed at a plurality of positions to be independent from each other by a normal process. Specifically, the patterning is performed by applying a photoresist film to the surface of the N-type epitaxial layer 11b with a predetermined pattern. Thereafter, the ion implantation of phosphorus (P) as N-type impurities is performed on the surface layer portion of the N-type epitaxial layer 11b to form the N-type charge storage layers 13a at a plurality of positions surrounded by the element isolation regions 15. At this time, the peak depth of the P concentration is determined mainly depending on the amount of the energy when implanting P ions.

In the present embodiment, the depth position of the bottom portion 19ab of the hollow, i.e., the depth position of the upper end portion 17u of the first element isolation units is set to the position that is deep equal to or more than the set depth position of the lower end portion 13ab of the charge storage layer. The set depth position of the lower end portion 13ab of the charge storage layer is set to the depth position equal to or more than the depth that light of each color of blue light, green light, and red light reaches for each light receiving element. In the present embodiment, the thickness of the N-type epitaxial layer 11b is, for example, 4 μm with the depth that red light reaches from the light receiving surface in the semiconductor substrate 11 as a reference.

The set depth position of the lower end portion 13ab of the charge storage layer is set to, for example, about 320 nm with the depth that blue light and green light reach from the light receiving surface in the semiconductor substrate 11 as a reference, and is set to, for example, about 790 nm with the depth that green light reaches from the light receiving surface in the semiconductor substrate 11 as a reference. The depth position of the bottom portion 19ab of the hollow, i.e., the depth position of the upper end portion 17u of the first element isolation units, is about 320 nm to 790 nm with the depth that blue light and green light reach from the light receiving surface in the semiconductor substrate 11 as a reference.

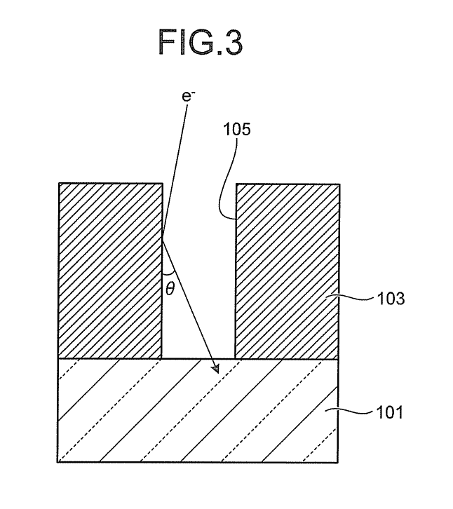

When the ion implantation is performed in multiple stages, the aspect ratio of an opening 105 of a mask layer 103 provided in the ion implantation region in the ion implantation becomes high with the progress of miniaturization, so that the acceleration energy loss at the time of the ion implantation to a semiconductor substrate 101 increases. A high scattering probability I of ions at the time of the ion implantation becomes a factor for the acceleration energy loss. The scattering probability I at the time of the ion implantation is typically expressed by the following Equations (1) and (2) (see FIG. 3). FIG. 3 is a schematic diagram for explaining the scattering probability when the ion implantation is performed on the semiconductor substrate 101 from the opening 105 of the mask layer 103.

$$\begin{matrix}I = \frac{1}{{sin}^{4} ( θ / 2 ) E} & ( 1 ) \\ θ ∝ {( \frac{α , β}{E} )}^{2} & ( 2 )\end{matrix}$$

where θ is an incident angle with respect to an inner wall of a mask layer, E is an incident energy, α is an atomic number of an incident ion, and β is an atomic number of a colliding material.

In other words, the scattering probability of the acceleration energy at the time of the ion implantation is calculated from the incident angle θ when an ion collides with an inner wall of an opening of a mask material at the time of the ion implantation, the incident energy E, the atomic number a of an incident ion, and the atomic number β of a colliding material, and becomes high as the incident energy E becomes low and becomes low as the atomic number β of the colliding material becomes small. Therefore, the incident energy becomes large at the time of the ion implantation.

The tendency of the acceleration energy loss is remarkable in the ion implantation condition with low acceleration energy, and the impurity concentration of the element isolation layer on the surface layer side of the semiconductor substrate becomes high. In this case, the element isolation layer expands to the light receiving element region due to the thermal diffusion and therefore the volume of the light receiving element region decreases, which results in decrease in the number of saturated electrons and influence (color mixing) on the adjacent light receiving element.

However, in the present embodiment, the depth position of the bottom portion 19ab of the hollow, i.e., the depth position of the upper end portion 17u of the first element isolation units is set to the position that is deep equal to or more than the set depth of the lower end portion 13ab of the charge storage layer. Therefore, even when the first element isolation unit 17 expands in the direction of the charge storage layer 13a, the first element isolation unit 17 does not penetrate the light receiving element region effective for the photoelectric conversion in the N-type charge storage layer 13a, so that the volume of the effective light receiving element region of the charge storage layer 13a can be prevented from decreasing due to the first element isolation unit 17. Thus, decrease in the number of saturated electrons in the N-type charge storage layer 13a and the influence (color mixing) on the adjacent light receiving element due to the expansion of the first element isolation unit 17 can be prevented.

Moreover, in order to implant ions to the deep position of the semiconductor substrate 11, the ion acceleration energy needs to be increased by increasing the valence of an ion, which results in requiring a long time for the ion implantation. However, in the present embodiment, because the hollow 19a is present in the surface layer portion of the semiconductor substrate 11, the depth to which ions are implanted for forming the element isolation layer in the semiconductor substrate 11 becomes shallow, so that the ion implantation can be performed with an ion having a low valence, so that the time required for the ion implantation can be shortened.

Furthermore, because the depth to which ions are implanted in the semiconductor substrate 11 becomes shallow, the maximum acceleration energy at the time of the ion implantation can be lowered compared with a conventional technology and the number of times of the ion implantation and the implantation amount can be reduced, so that the throughput is increased. Whereby, the cost for the ion implantation process can be reduced.

Thereafter, components needed for a signal readout and a reset operation of the CMOS image sensor, such as the readout gate electrode 21, an amplifier gate, and a reset gate, are formed to complete the CMOS image sensor as shown in FIG. 2F via a process same as a process for a general-purpose logic device.

In the manufacturing method of the semiconductor device according to the present embodiment configured as above, the element isolation region 15 that includes a plurality of the first element isolation units 17 composed of the P-type semiconductor layers and the second element isolation unit 19 having the SON structure is formed in the region surrounding the charge storage layer 13a of the photodiode 13 in the in-plane direction of the semiconductor substrate 11, and the element isolation region 15 is connected to the P-type semiconductor substrate 11a. Consequently, the charge storage layers 13a of the photodiodes 13 can be electrically isolated from each other by individually and three-dimensionally (sterically) surrounding them by the element isolation regions 15 and the P-type semiconductor substrate 11a.

The depth position of the bottom portion 19ab of the hollow, i.e., the depth position of the upper end portion 17u of the first element isolation units, is set to the position that is deep equal to or more than the set depth position of the lower end portion 13ab of the charge storage layer, so that the first element isolation unit 17 does not penetrate the light receiving element region effective for the photoelectric conversion in the charge storage layer 13a, so that the volume of the effective light receiving element region of the charge storage layer 13a can be prevented from decreasing due to the first element isolation unit 17. Therefore, decrease in the number of saturated electrons and the influence (color mixing) on the adjacent light receiving element due to the expansion of the first element isolation unit 17 can be prevented.

Thus, according to the manufacturing method of the semiconductor device in the present embodiment, it is possible to manufacture a high-quality semiconductor device, in which adjacent photodiodes 13 are electrically isolated from each other certainly and which prevent decrease in the number of saturated electrons and the color mixing of the light receiving element due to the expansion of the element isolation layer even with the progress of miniaturization.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A solid-state imaging device comprising:
a first-conductive semiconductor layer;
a second-conductive semiconductor layer that is provided on the first-conductive semiconductor layer;
a light receiving element that is formed in the second-conductive semiconductor layer; and
an element isolation region that is formed to surround the light receiving element in an in-plane direction of the second-conductive semiconductor layer, wherein
the element isolation region includes
a first-conductive first element isolation unit that is connected to the first-conductive semiconductor layer,
a hollow that is formed on the first-conductive first element isolation unit, and
a first-conductive second element isolation unit that is formed on the hollow.

2. The solid-state imaging device according to claim 1, wherein an impurity concentration on a surface layer side of the second-conductive semiconductor layer is higher than an impurity concentration on a side of the first-conductive semiconductor layer, in the first-conductive first element isolation unit.

3. The solid-state imaging device according to claim 1, wherein an element isolation width on a surface layer side of the second-conductive semiconductor layer is larger than an element isolation width on a side of the first-conductive semiconductor layer, in the first-conductive first element isolation unit.

4. The solid-state imaging device according to claim 1, wherein a depth from a surface of the second-conductive semiconductor layer to a bottom portion of the hollow is larger than a wavelength of blue light and is smaller than a wavelength of green light.

5. The solid-state imaging device according to claim 1, wherein a depth from a surface of the second-conductive semiconductor layer to a bottom portion of the hollow is 320 nm to 790 nm.

6. The solid-state imaging device according to claim 1, wherein a thickness of the second-conductive semiconductor layer is larger than a wavelength of red light.

7. The solid-state imaging device according to claim 1, wherein the light receiving element surrounded by the element isolation region is formed in an array in the in-plane direction of the second conductive semiconductor layer.

8. A method of manufacturing a solid-state imaging device comprising:
forming a second-conductive semiconductor layer on a first-conductive semiconductor layer;
forming an opening to surround a predetermined region of the second-conductive semiconductor layer in an in-plane direction of the second-conductive semiconductor layer;
forming a hollow by sealing the opening through a thermal treatment to the second-conductive semiconductor layer in a non-oxidative atmosphere;
forming a pattern in which a region corresponding to the hollow is open on the second-conductive semiconductor layer;
forming an element isolation unit by performing an ion implantation of a first-conductive ion on the second-conductive semiconductor layer with the pattern as a mask; and
forming a light receiving element on the second-conductive semiconductor layer surrounded by the element isolation unit and the hollow in the in-plane direction of the second-conductive semiconductor layer.

9. The method according to claim 8, wherein the forming the element isolation unit includes performing the ion implantation of the first-conductive ion on the second-conductive semiconductor layer at a lower portion of the hollow a plurality of times while changing an implantation depth of an ion.

10. The method according to claim 8, wherein a depth of the opening is 320 nm to 790 nm.

11. The method according to claim 8, wherein a thickness of the second-conductive semiconductor layer is larger than a wavelength of red light.

12. The method according to claim 8, further comprising forming the light receiving element surrounded by the element isolation unit and the hollow in an array in the in-plane direction of the second-conductive semiconductor layer.
